(19) United States
(12) Patent Application Publication
(10) Pub. No.: US 2025/0212382 A1
(43) Pub. Date: Jun. 26, 2025

(54) SEMICONDUCTOR DEVICE INCLUDING DIELECTRIC LAYER WITH UNEVEN THICKNESS

(71) Applicant: NANYA TECHNOLOGY CORPORATION, NEW TAIPEI CITY (TW)

(72) Inventor: CHAO-WEN LAY, NEW TAIPEI CITY (TW)

(21) Appl. No.: 18/974,866

(22) Filed: Dec. 10, 2024

Related U.S. Application Data
(63) Continuation-in-part of application No. 18/395,797, filed on Dec. 26, 2023.

(51) Int. Cl. H10B 12/00

(52) U.S. Cl. CPC H10B 12/053; H10B 12/315; H10B 12/34; H10B 12/482; H10B 12/485

(57) ABSTRACT

A semiconductor device and method for manufacturing the same are provided. The semiconductor device includes a substrate, a dielectric layer, and a gate electrode. The dielectric layer is at least partially embedded within the substrate. The dielectric layer has a first portion with a first thickness and a second portion with a second thickness less than the first thickness. The gate electrode is spaced apart from the substrate by the first portion of the dielectric layer.

### CROSS-REFERENCE TO RELATED APPLICATION

This application is a continuation-in-part application of U.S. Non-Provisional application Ser. No. 18/395,797 filed Dec. 26, 2023, which is incorporated herein by reference in its entirety.

### TECHNICAL FIELD

The present disclosure relates to a semiconductor device and method for manufacturing the same, and more particularly, to a semiconductor device including a dielectric layer with an uneven thickness and a method for manufacturing the same.

### DISCUSSION OF THE BACKGROUND

Semiconductor devices are used in various electronic applications, including personal computers, cellular telephones, digital cameras, and other electronic equipment. Sizes of semiconductor devices are continuously decreasing to meet growing demands for computing power. However, such scaling down presents challenges that are becoming more frequent and impactful. Therefore, there are still challenges to improving quality, yield, performance and reliability while reducing complexity.

As the semiconductor industry progresses, aspect ratios of trenches in substrates are increasing, which adversely affects formation of gate electrodes within the trenches. For example, voids may develop at a bottom of the trench, resulting in electrical properties that fail to meet necessary specifications. Therefore, there is an urgent need for new semiconductor devices and innovative methods to tackle these challenges.

This Discussion of the Background section is provided for background information only. The statements in this Discussion of the Background are not an admission that the subject matter disclosed in this Discussion of the Background section constitutes prior art to the present disclosure, and no part of this Discussion of the Background section may be used as an admission that any part of this application, including this Discussion of the Background section, constitutes prior art to the present disclosure.

### SUMMARY

One aspect of the present disclosure provides a semiconductor device. The semiconductor device comprises a substrate with a top surface, wherein the substrate includes an active area comprising an upper region and a lower region, wherein the upper region contains a plurality of doped regions; a dielectric layer at least partially embedded within the substrate; a gate electrode spaced apart from the substrate by a first portion of the dielectric layer; and a bit line positioned in and protruding from the active area. The dielectric layer includes the first portion with a first thickness and a second portion with a second thickness less than the first thickness. The bit line comprises a bit line contact located in the upper region of the active area. A top surface of the bit line contact is at a vertical level same as a vertical level of the top surface of the substrate.

In some embodiments, the bit line is positioned between two gate electrodes.

In some embodiments, the bit line is configured to electrically connect one of the doped regions to a bit line structure.

In some embodiments, the bit line comprises a bit line bottom electrode, a bit line top electrode, a bit line mask pattern, and a bit line spacer.

In some embodiments, a bottom surface of the bit line bottom electrode is substantially coplanar with the top surface of the bit line contact; a bottom surface of the bit line top electrode is substantially coplanar with a top surface of the bit line bottom electrode; and a bottom surface of the bit line mask pattern is substantially coplanar with a top surface of the bit line top electrode.

In some embodiments, a top surface of the bit line spacer is substantially coplanar with a top surface of the bit line mask pattern, and a bottom surface of the bit line spacer is substantially coplanar with a bottom surface of the bit line contact.

In some embodiments, sidewalls of the bit line contact, the bit line bottom electrode, the bit line top electrode, the bit line mask pattern, and the bit line spacer are substantially coplanar.

In some embodiments, the semiconductor device further comprises a conductive plug positioned on the substrate, configured to electrically connect to one of the doped regions of the active area; a capacitor electrode landing pad disposed over and covering the conductive plug; and a capacitor structure disposed over the capacitor electrode landing pad and electrically connected to the conductive plug.

In some embodiments, the capacitor structure comprises a capacitor bottom electrode disposed over the capacitor electrode landing pad, a capacitor top electrode disposed over the capacitor bottom electrode, and a capacitor dielectric disposed between the capacitor bottom electrode and the capacitor top electrode, wherein the capacitor bottom electrode includes a lower portion disposed over the capacitor electrode landing pad and an upper portion disposed over the lower portion.

In some embodiments, the lower portion of the capacitor bottom electrode has a tapered profile.

Another aspect of the present disclosure provides a semiconductor device. The semiconductor device comprises a substrate; a gate dielectric embedded within the substrate; a gate electrode spaced apart from the substrate by the gate dielectric; a dielectric structure disposed over the gate electrode; a bit line positioned in a top surface of the substrate and between two of the gate electrodes; a conductive plug positioned on the substrate and electrically connected to a doped region of the substrate; and a capacitor disposed over and electrically connected to the conductive plug. The dielectric structure includes a step profile. The conductive plug consists of a first part disposed on the substrate and a second part disposed on the first part and within the dielectric structure.

In some embodiments, the semiconductor device further comprises a capacitor electrode landing pad disposed over and covering the conductive plug.

In some embodiments, the bit line is configured to electrically connect one of the doped regions to a bit line structure.

In some embodiments, the bit line comprises a bit line bottom electrode, a bit line top electrode, a bit line mask pattern, and a bit line spacer.

In some embodiments, a bottom surface of the bit line bottom electrode is substantially coplanar with a top surface of a bit line contact; a bottom surface of the bit line top electrode is substantially coplanar with a top surface of the bit line bottom electrode; and a bottom surface of the bit line mask pattern is substantially coplanar with a top surface of the bit line top electrode.

In some embodiments, a top surface of the bit line spacer is substantially coplanar with a top surface of the bit line mask pattern, and a bottom surface of the bit line spacer is substantially coplanar with a bottom surface of the bit line contact.

In some embodiments, sidewalls of the bit line contact, the bit line bottom electrode, the bit line top electrode, the bit line mask pattern, and the bit line spacer are substantially coplanar.

In some embodiments, the capacitor comprises a capacitor bottom electrode disposed on the capacitor electrode landing pad, a capacitor top electrode disposed over the capacitor bottom electrode, and a capacitor dielectric disposed between the capacitor bottom electrode and the capacitor top electrode. The capacitor bottom electrode includes a lower portion disposed over the capacitor electrode landing pad and an upper portion disposed over the lower portion.

In some embodiments, the lower portion of the capacitor bottom electrode has a tapered profile.

In some embodiments, the second part of the conductive plug is formed using an electroplating process.

Another aspect of the present disclosure provides a method of manufacturing a semiconductor device. The method comprises providing a substrate with a top surface; forming an active area in the substrate, wherein the active area includes an upper region and a lower region, wherein the upper region includes a plurality of doped regions; forming a dielectric layer at least partially embedded within the substrate; forming a gate electrode spaced apart from the substrate by the dielectric layer; and forming a bit line in and protruding from the active area of the substrate, wherein the bit line comprises a bit line contact in the upper region of the active area, and a top surface of the bit line contact is at a vertical level same as a vertical level of the top surface of the substrate.

In some embodiments, the formation of the dielectric layer comprises forming a first portion of the dielectric layer with a first thickness and forming a second portion with a second thickness less than the first thickness.

In some embodiments, the formation of the bit line further comprises forming a bit line bottom electrode over the bit line contact; forming a bit line top electrode over the bit line bottom electrode; forming a bit line mask pattern over the bit line top electrode; and forming a bit line spacer on sidewalls of the bit line contact, the bit line bottom electrode, the bit line top electrode, and the bit line mask pattern.

In some embodiments, a bottom surface of the bit line bottom electrode is substantially coplanar with the top surface of the bit line contact; a bottom surface of the bit line top electrode is substantially coplanar with a top surface of the bit line bottom electrode; and a bottom surface of the bit line mask pattern is substantially coplanar with a top surface of the bit line top electrode.

In some embodiments, a top surface of the bit line spacer is substantially coplanar with a top surface of the bit line mask pattern, and a bottom surface of the bit line spacer is substantially coplanar with a bottom surface of the bit line contact.

In some embodiments, the method further comprises forming a conductive plug on the substrate; forming a capacitor electrode landing pad over and covering the conductive plug; and forming a capacitor structure over the capacitor electrode landing pad and electrically connected to the conductive plug.

Another aspect of the present disclosure provides a method of manufacturing a semiconductor device. The method comprises providing a substrate; forming a gate dielectric at least partially embedded within the substrate; forming a gate electrode spaced apart from the substrate by the gate dielectric; forming an isolation structure over the substrate and surrounding the gate dielectric; forming a dielectric structure over the gate electrode and the isolation structure; forming a bit line in a top surface of the substrate and between two of the gate electrodes; forming a conductive plug over the substrate; forming a capacitor electrode landing pad over and covering the conductive plug; and forming a capacitor over and electrically connected to the conductive plug. The dielectric structure includes a step profile. The conductive plug includes a first part disposed within the isolation structure and a second part disposed over the first part and exposed by the isolation structure. The formation of the capacitor electrode landing pad comprises electroplating the second part of the conductive plug.

In some embodiments, the formation of the bit line further comprises forming a bit line bottom electrode over a bit line contact; forming a bit line top electrode over the bit line bottom electrode; forming a bit line mask pattern over the bit line top electrode; and forming a bit line spacer on sidewalls of the bit line contact, the bit line bottom electrode, the bit line top electrode, and the bit line mask pattern.

In some embodiments, the formation of the capacitor comprises forming a capacitor bottom electrode over the capacitor electrode landing pad; forming a capacitor top electrode over the capacitor bottom electrode; and forming a capacitor dielectric between the capacitor bottom electrode and the capacitor top electrode.

In some embodiments, the formation of the capacitor bottom electrode comprises forming a lower portion over the capacitor electrode landing pad and forming an upper portion over the lower portion.

The embodiments of the present disclosure illustrate a semiconductor device that includes a dielectric layer located within a trench defined by a substrate. The dielectric layer features a lower portion with a greater thickness and an upper portion with a smaller thickness. Such structure facilitates the deposition of a conductive material(s) to form a gate electrode without formation of voids within the trench, thereby enhancing a performance of the semiconductor device.

The foregoing has outlined rather broadly the features and technical advantages of the present disclosure in order that the detailed description of the disclosure that follows may be better understood. Additional features and advantages of the disclosure are described below, and form the subject of the claims of the disclosure. It should be appreciated by those skilled in the art that the conception and specific embodiments disclosed may be readily utilized as a basis for modifying or designing other structures or processes for carrying out the purposes of the present disclosure. It should also be realized by those skilled in the art that such equivalent constructions do not depart from the spirit and scope of the disclosure as set forth in the appended claims.

### BRIEF DESCRIPTION OF THE DRA WINGS

Aspects of the present disclosure are best understood from the following detailed description when read with the accompanying figures. It should be noted that, in accordance with the standard practice in the industry, various features are not drawn to scale. In fact, the dimensions of the various features may be arbitrarily increased or reduced for clarity of discussion.

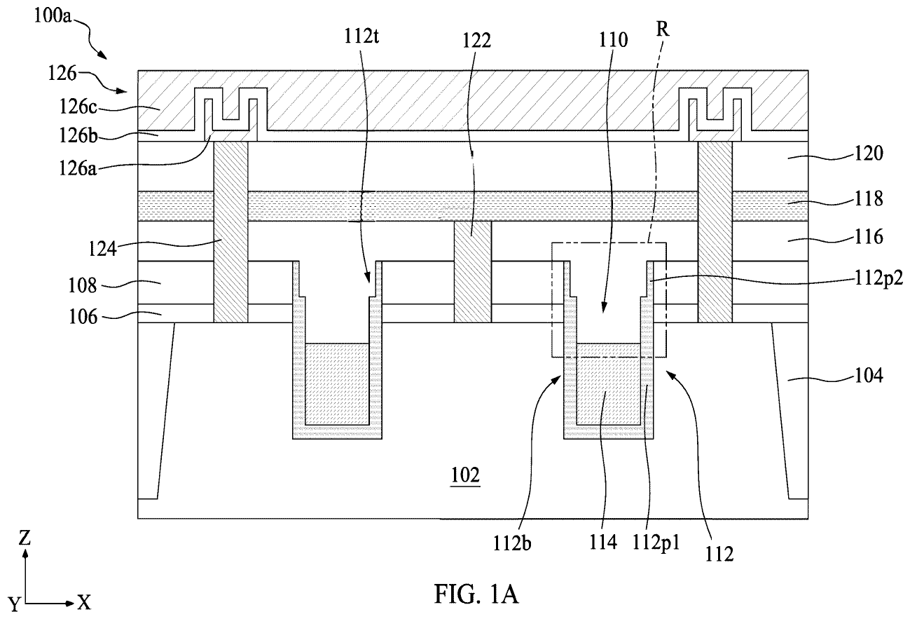

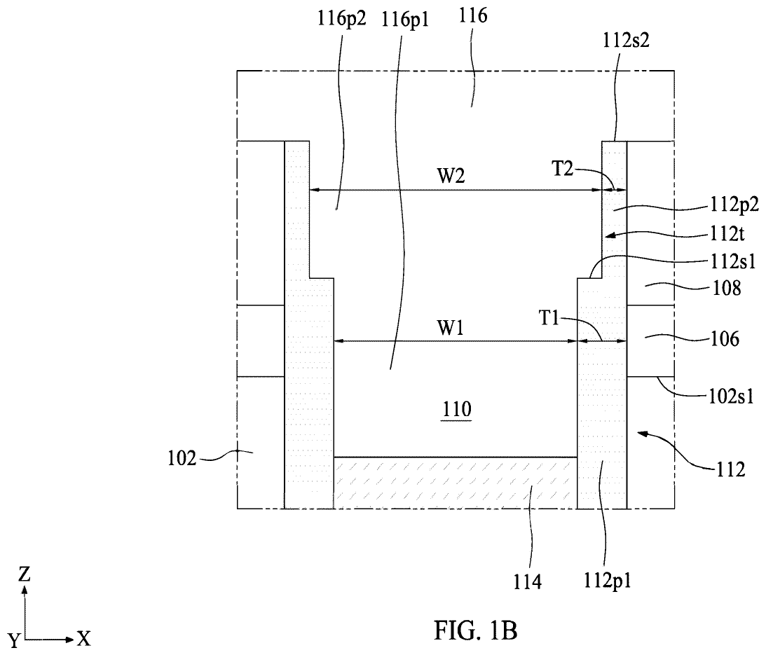

FIG. 1A is a cross-sectional view of a semiconductor device in accordance with some embodiments of the present disclosure.

FIG. 1B is a partial enlarged view of a region R of the semiconductor device shown in FIG. 1A, in accordance with some embodiments of the present disclosure.

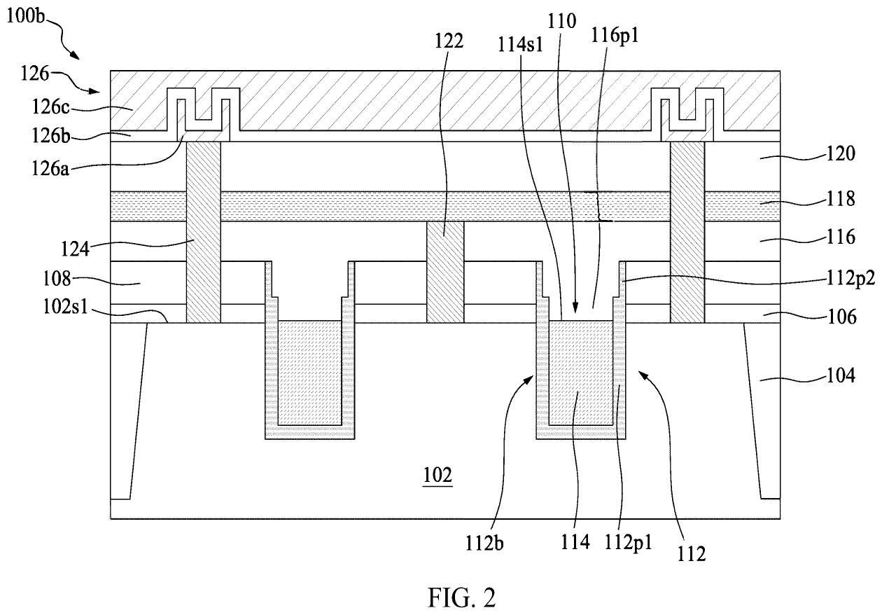

FIG. 2 is a cross-sectional view of a semiconductor device, in accordance with some embodiments of the present disclosure.

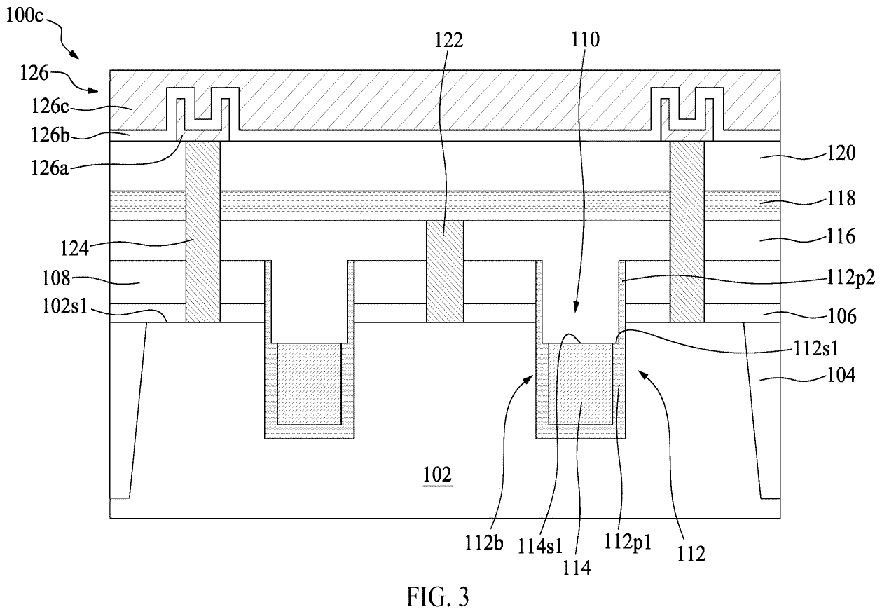

FIG. 3 is a cross-sectional view of a semiconductor device, in accordance with some embodiments of the present disclosure.

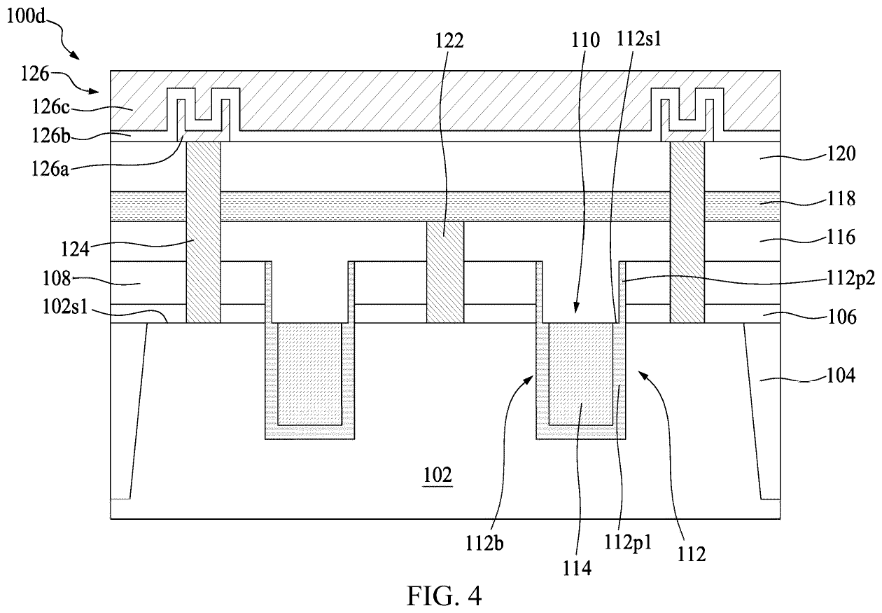

FIG. 4 is a cross-sectional view of a semiconductor device, in accordance with some embodiments of the present disclosure.

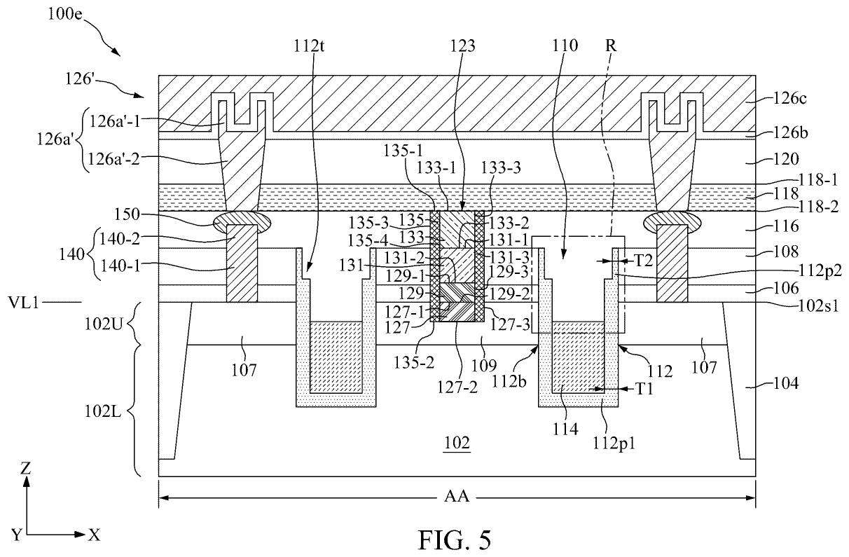

FIG. 5 is a cross-sectional view of a semiconductor device, in accordance with some embodiments of the present disclosure.

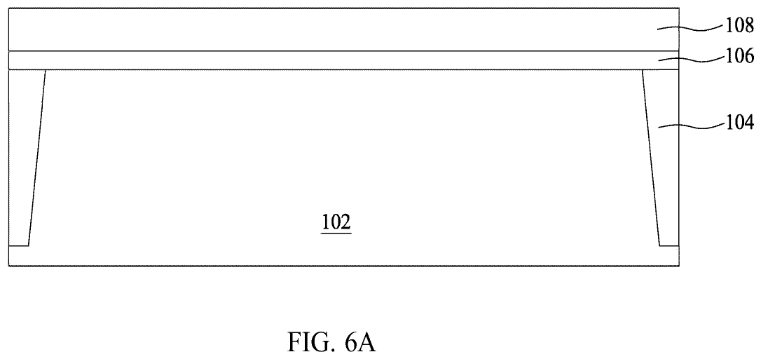

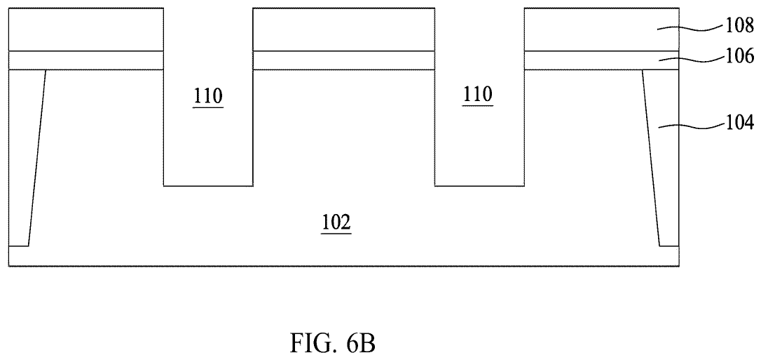

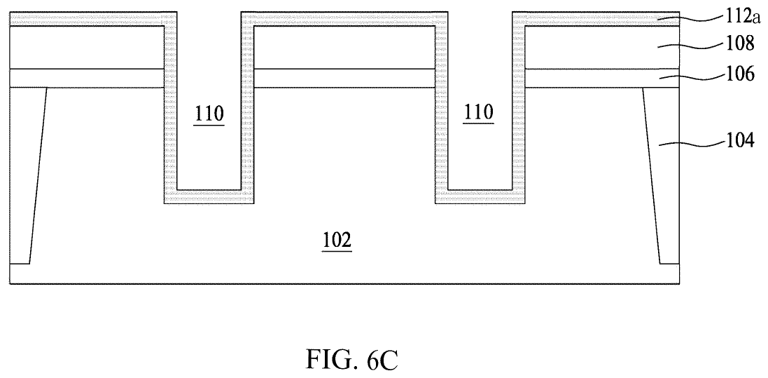

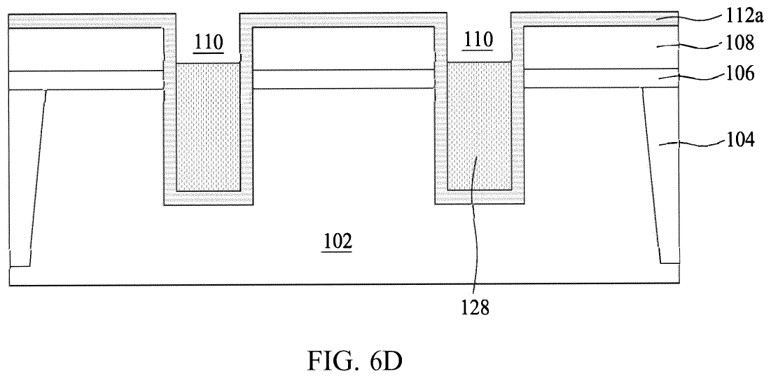

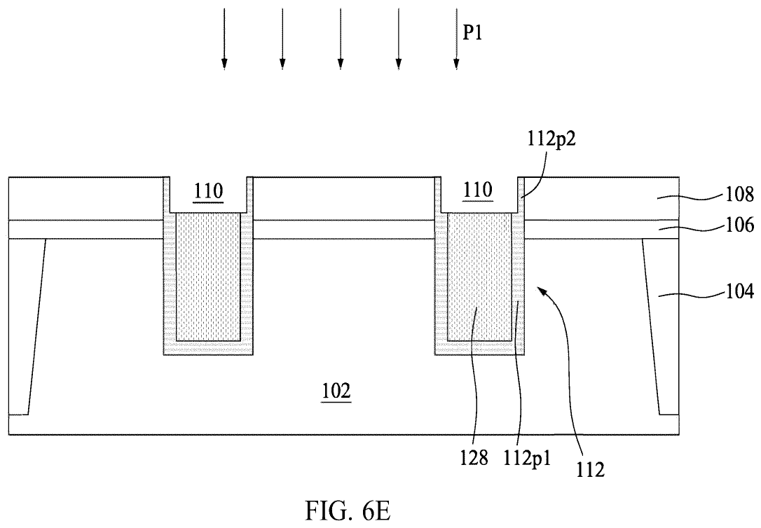

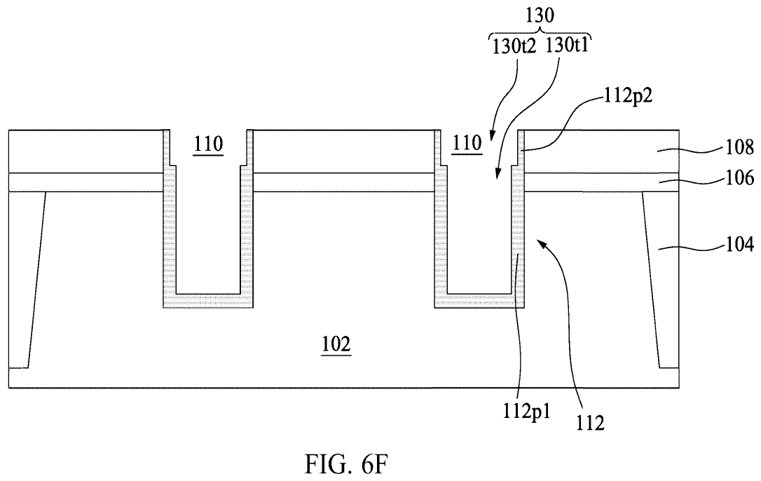

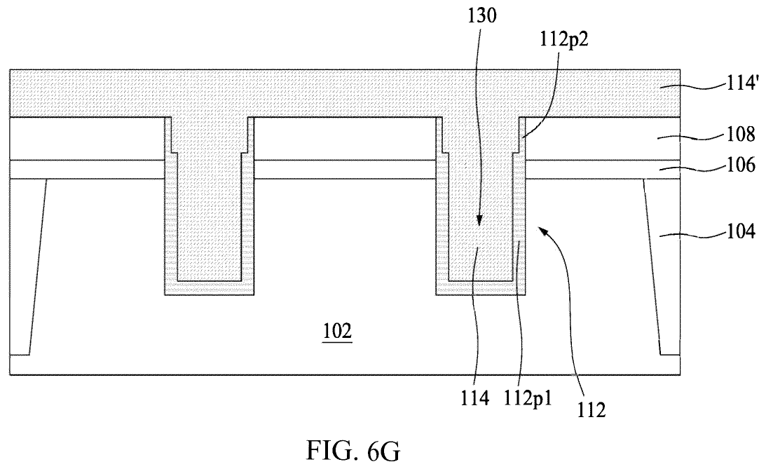

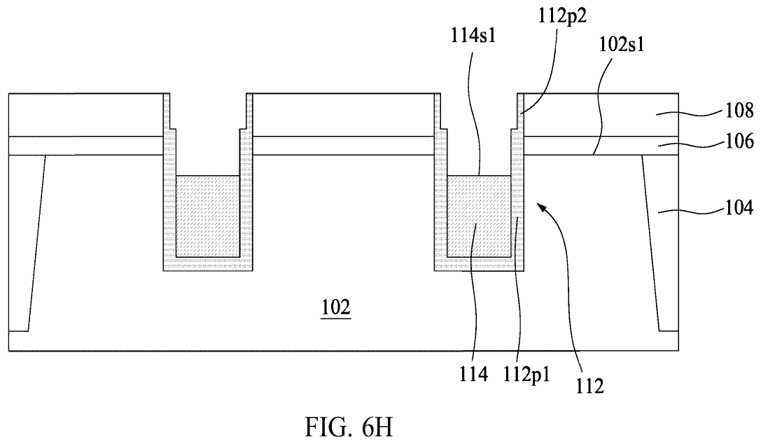

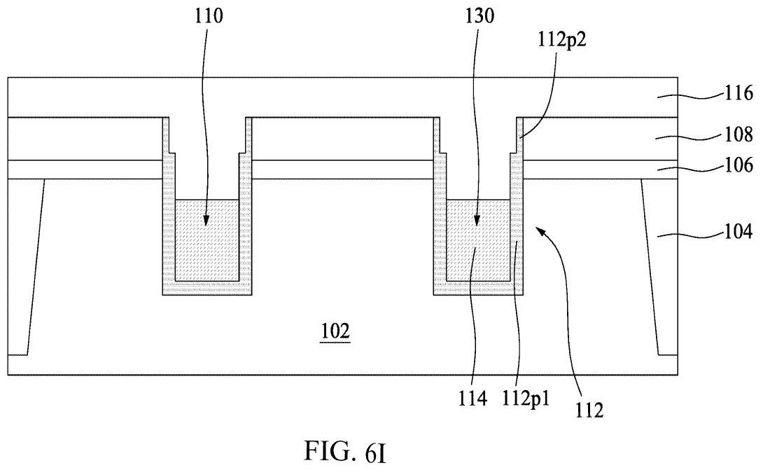

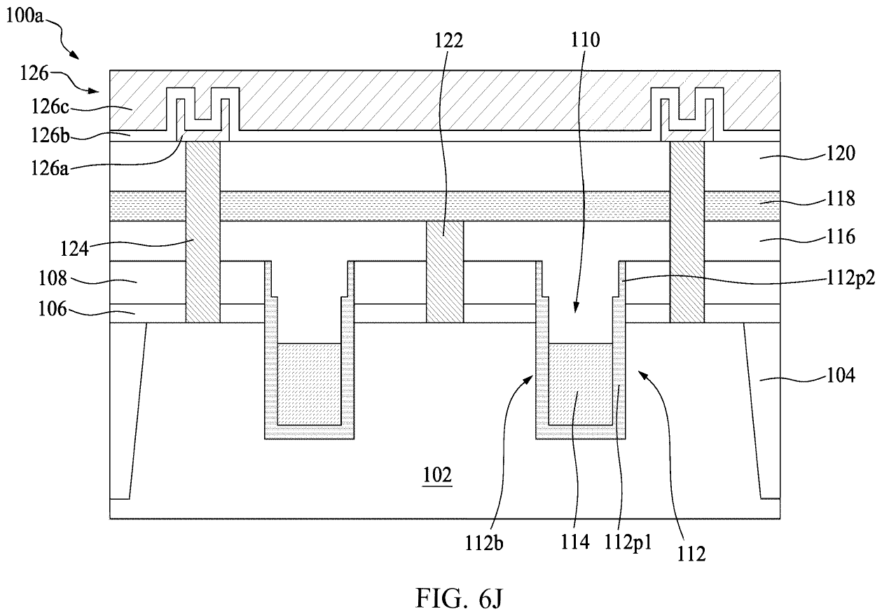

FIG. 6A illustrates one or more stages of an exemplary method for manufacturing a semiconductor device in accordance with some embodiments of the present disclosure.

FIG. 6B illustrates one or more stages of an exemplary method for manufacturing a semiconductor device in accordance with some embodiments of the present disclosure.

FIG. 6C illustrates one or more stages of an exemplary method for manufacturing a semiconductor device in accordance with some embodiments of the present disclosure.

FIG. 6D illustrates one or more stages of an exemplary method for manufacturing a semiconductor device in accordance with some embodiments of the present disclosure.

FIG. 6E illustrates one or more stages of an exemplary method for manufacturing a semiconductor device in accordance with some embodiments of the present disclosure.

FIG. 6F illustrates one or more stages of an exemplary method for manufacturing a semiconductor device in accordance with some embodiments of the present disclosure.

FIG. 6G illustrates one or more stages of an exemplary method for manufacturing a semiconductor device in accordance with some embodiments of the present disclosure.

FIG. 6H illustrates one or more stages of an exemplary method for manufacturing a semiconductor device in accordance with some embodiments of the present disclosure.

FIG. 6I illustrates one or more stages of an exemplary method for manufacturing a semiconductor device in accordance with some embodiments of the present disclosure.

FIG. 6J illustrates one or more stages of an exemplary method for manufacturing a semiconductor device in accordance with some embodiments of the present disclosure.

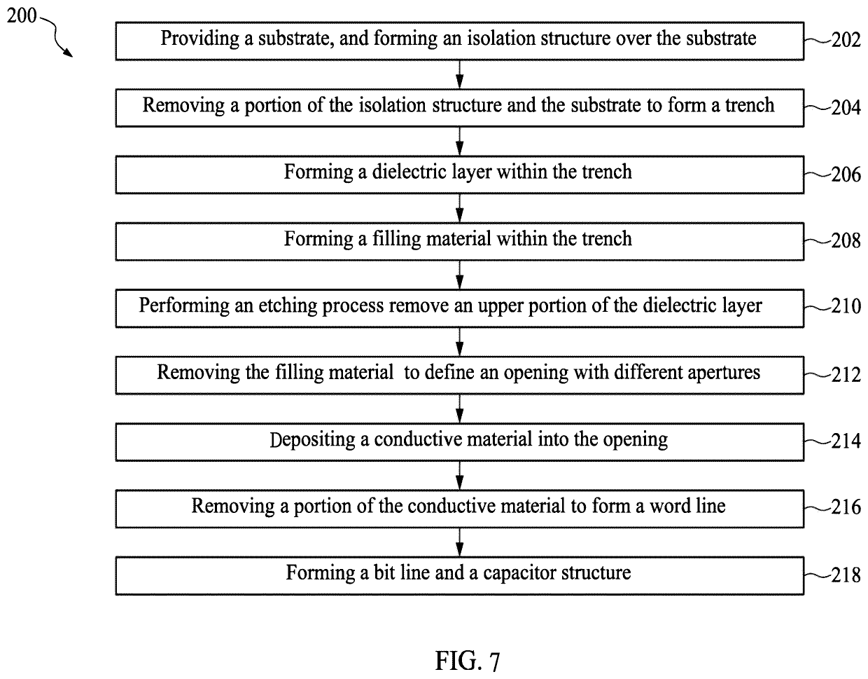

FIG. 7 is a flowchart illustrating a method of manufacturing a semiconductor device, in accordance with some embodiments of the present disclosure.

### DETAILED DESCRIPTION

Embodiments, or examples, of the disclosure illustrated in the drawings are now described using a specific language. It shall be understood that no limitation of the scope of the disclosure is hereby intended. Any alteration or modification of the described embodiments, and any further applications of principles described in this document, are to be considered as normally occurring to one of ordinary skill in the art to which the disclosure relates. Reference numerals may be repeated throughout the embodiments, but this does not necessarily mean that feature(s) of one embodiment apply to another embodiment, even if they share the same reference numeral.

It should be understood that, although the terms first, second, third, etc. may be used herein to describe various elements, components, regions, layers or sections, these elements, components, regions, layers or sections are not limited by these terms. Rather, these terms are merely used to distinguish one element, component, region, layer or section from another element, component, region, layer or section. Thus, a first element, component, region, layer or section discussed below could be termed a second element, component, region, layer or section without departing from the teachings of the present inventive concept.

The terminology used herein is for the purpose of describing particular example embodiments only and is not intended to be limiting to the present inventive concept. As used herein, the singular forms “a,” “an” and “the” are intended to include the plural forms as well, unless the context clearly indicates otherwise. It should be understood that the terms “comprises” and “comprising,” when used in this specification, point out the presence of stated features, integers, steps, operations, elements, or components, but do not preclude the presence or addition of one or more other features, integers, steps, operations, elements, components, or groups thereof.

FIG. 1A is a cross-sectional view of a semiconductor device 100a in accordance with some embodiments of the present disclosure.

With reference to FIG. 1A, in some embodiments, the semiconductor device 100a may include a cell region where a memory device is formed. The memory device may consist of, for example, a dynamic random-access memory (DRAM) device, a one-time programmable (OTP) memory device, a static random-access memory (SRAM) device, or other suitable memory devices. In some embodiments, a DRAM may include, for example, a transistor, a capacitor, and additional components. Furthermore, the semiconductor device 100a may also feature a peripheral region where a transistor is formed.

During a read operation, a word line is asserted, activating the transistor. The enabled transistor allows a voltage across a capacitor to be read by a sense amplifier via a bit line. In a write operation, a data to be written is provided on the bit line when the word line is asserted.

The semiconductor device 100a may include a substrate 102, which can be a semiconductor substrate such as a bulk semiconductor, a semiconductor-on-insulator (SOI) substrate, or the like. The substrate 102 may consist of an elementary semiconductor including silicon or germanium in a single crystal, or polycrystalline or amorphous forms; a compound semiconductor material comprising at least one of silicon carbide, gallium arsenide, gallium phosphide, indium phosphide, indium arsenide, and indium antimonide; or an alloy semiconductor material that includes at least one of SiGe, GaAsP, AlInAs, AlGaAs, GaInAs, GaInP, and GaInAsP. In some embodiments, the substrate may comprise any other suitable material, or a combination thereof.

In some embodiments, the alloy semiconductor substrate may be a SiGe alloy featuring a gradient Si:Ge composition, where the Si/Ge ratio varies from one location to another within the gradient. In another embodiment, the SiGe alloy is formed over a silicon substrate. Furthermore, the SiGe alloy may be mechanically strained by another material in contact with the SiGe alloy. The substrate 102 may also have a multilayered structure, or may include a multilayered compound semiconductor structure.

In some embodiments, the substrate 102 may contain multiple active areas, which function as channels for electrical connection. Dopants may be introduced into the substrate 102 to form the active areas. In some embodiments, the dopants can be of n-type and/or p-type. N-type dopants may include arsenic (As), phosphorus (P), other group V elements, or a combination thereof. In some embodiments, the first conductive type is p-type, with p-type dopants including boron (B), other group III elements, or a combination thereof

In some embodiments, the semiconductor device 100a may include an electrical isolation region 104, which can consist of a shallow trench isolation (STI). The electrical isolation region 104 may separate the multiple active areas. In some embodiments, the electrical isolation region 104 may be embedded within the substrate 102. In some embodiments, the electrical isolation region 104 may comprise materials such as silicon oxide (SiO₂), silicon nitride (Si₃N₄), silicon oxynitride (N₂OSi₂), silicon nitride oxide (N₂OSi₂), or other suitable materials.

In some embodiments, the semiconductor device 100a may include a dielectric layer 106, which is disposed on the substrate 102. The dielectric layer 106 may also cover the electrical isolation region 104. In some embodiments, the dielectric layer 106 may comprise materials such as silicon oxide (SiO₂), silicon nitride (Si₃N₄), silicon oxynitride (N₂OSi₂), silicon nitride oxide (N₂OSi₂), or other suitable materials.

In some embodiments, the semiconductor device 100a may include a dielectric layer 108, which is disposed on the dielectric layer 106. In some embodiments, the dielectric layer 108 may comprise materials such as silicon nitride (Si₃N₄), silicon oxide (SiO₂), silicon oxynitride (N₂OSi₂), silicon nitride oxide (N₂OSi₂), or other suitable materials. Dimensions (e.g., thickness) of the dielectric layers 106 and 108 may differ; for instance, the thickness of the dielectric layer 108 may be greater than the thickness of the dielectric layer 106. In some embodiments, a material of the dielectric layer 108 may differ from a material of the dielectric layer 106. For example, the dielectric layer 106 may consist of silicon oxide (SiO₂), while dielectric layer 108 may consist of silicon nitride (Si₃N₄). In some embodiments, either the dielectric layer 106, the dielectric layer 108, or both may be referred to as an isolation structure.

In some embodiments, the substrate 102, the dielectric layer 106, and/or the dielectric layer 108 may define trenches 110. The trench 110 may extend through a portion of the substrate 102. The trench 110 may penetrate the dielectric layers 106 and 108. The trenches 110 are configured to accommodate a gate stack, which includes a gate dielectric, a gate electrode, and/or other suitable elements.

In some embodiments, the semiconductor device 100a may include a dielectric layer 112. In some embodiments, the dielectric layer 112 may be disposed within the trench 110. In some embodiments, the dielectric layer 112 may be disposed on a sidewall (or a lateral surface) of the substrate 102. In some embodiments, the dielectric layer 112 may be disposed on a surface of the substrate 102. In some embodiments, the dielectric layer 112 may be in contact with the substrate 102. In some embodiments, the dielectric layer 112 may be disposed on a sidewall (or a lateral surface) of the dielectric layer 106. In some embodiments, the dielectric layer 112 may be in contact with the dielectric layer 106. In some embodiments, the dielectric layer 112 may be disposed on a sidewall (or a lateral surface) of the dielectric layer 108. In some embodiments, the dielectric layer 112 may be in contact with the dielectric layer 108.

In some embodiments, the dielectric layer 112 may comprise materials such as silicon nitride (Si₃N₄), silicon oxide (SiO₂), silicon oxynitride (N₂OSi₂), silicon nitride oxide (N₂OSi₂), or other high-k materials. High-k materials are defined as dielectric materials with a dielectric constant exceeding that of silicon dioxide (SiO₂), typically higher than about 3.9. In some embodiments, the dielectric layer 112 may include at least one metallic element, such as hafnium oxide (HfO₂), silicon doped hafnium oxide (HSO), lanthanum oxide (La₂O₃), lanthanum aluminum oxide (LaAlO₃), zirconium orthosilicate (ZrSiO₄), aluminum oxide (Al₂O₃) or a combination thereof. In some embodiments, the high-k dielectric material may be selected from metal oxides, metal nitrides, metal silicates, transition metal-oxides, transition metal-nitrides, transition-metal silicates, metal oxynitrides, metal aluminates, and a combination thereof.

In some embodiments, the semiconductor device 100a may include a gate electrode 114, which may be disposed within the trench 110 and positioned on the dielectric layer 112. The gate electrode 114 may be spaced apart from the substrate 102 by the dielectric layer 112. In some embodiments, the gate electrode 114 may consist of one or more materials, including a barrier layer and a conductive layer, with the conductive layer spaced apart from the dielectric layer 112 by the barrier layer. The barrier layer may comprise materials such as titanium (Ti), titanium nitride (TiN), tantalum (Ta), tantalum nitride (TaN), tungsten nitride (WN), tungsten carbon nitride (WCN), or the like. In some embodiments, the conductive layer may include tungsten (W), aluminum (Al), copper (Cu), other suitable materials, or a combination thereof.

In some embodiments, the gate electrode 114 may consist of multiple barrier layers and multiple conductive layers, with the layers separated by the barrier layers. In some embodiments, the gate electrode 114 may function as a word line structure in a DRAM device, extending along a Y direction. Furthermore, a portion of the dielectric layer 112 may serve as a gate dielectric 112b.

In some embodiments, the semiconductor device 100a may include a dielectric structure 116, which is disposed on the dielectric layer 108. A portion of the dielectric structure 116 may extend into the trench 110 and cover the gate electrode 114. In some embodiments, the dielectric structure 116 may be in contact with a sidewall of the dielectric layer 112.

The dielectric structure 116 may comprise materials such as silicon nitride (Si₃N₄), silicon oxide (SiO₂), silicon oxynitride (N₂OSi₂), silicon nitride oxide (N₂OSi₂), other suitable materials, or a combination thereof. In some embodiments, a material of the dielectric structure 116 may differ from a material of the dielectric layer 112. For example, the dielectric structure 116 may consist of silicon nitride (Si₃N₄), and the dielectric layer 112 may consist of silicon oxide (SiO₂).

In some embodiments, the semiconductor device 100a may include a bit line structure 118, which is disposed on the dielectric structure 116 and positioned over the word line that includes the gate electrode 114. The bit line structure 118 may extend along an X direction. In some embodiments, the bit line structure 118 may have a multilayered configuration. For example, the bit line structure 118 may include a conductive layer composed of polysilicon doped with n-type dopants, such as arsenic (As) or phosphorus (P). In some embodiments, the bit line structure 118 may incorporate materials such as titanium (Ti), tungsten (W), aluminum (Al), copper (Cu), other suitable materials, or a combination thereof.

In some embodiments, the semiconductor device 100a may include an isolation layer 120, which is disposed on the bit line structure 118. The isolation layer 120 may comprise materials such as silicon nitride (Si₃N₄), silicon oxide (SiO₂), silicon oxynitride, flowable oxide, tonen silazen, undoped silica glass, borosilica glass, phosphosilica glass, borophosphosilica glass, plasma-enhanced tetraethyl orthosilicate, fluoride silicate glass, carbon-doped silicon oxide, or a combination thereof. The isolation layer 120 may function as a hard mask designed to prevent the bit line structure 118 from damage during processes such as formation of capacitor structures.

In some embodiments, the semiconductor device 100a may include a conductive contact 122, which penetrates the dielectric structure 116, the dielectric layer 108, and the dielectric layer 106. The conductive contact 122 is configured to electrically connect an active region (e.g., a doped region within the substrate 102) to the bit line structure 118. The conductive contact 122 may comprise materials such as tungsten (W), cobalt (Co), zirconium (Zr), tantalum (Ta), titanium (Ti), aluminum (Al), ruthenium (Ru), copper (Cu), metal carbides (e.g., tantalum carbide (TaC), titanium carbide (TiC), or tantalum magnesium carbide (TaMaC)), metal nitrides (e.g., titanium nitride (TiN)), transition metal aluminides, or a combination thereof.

In some embodiments, the semiconductor device 100a may include a conductive contact 124. The conductive contact 124 may penetrate the isolation layer 120, the dielectric structure 116, the dielectric layer 108, and the dielectric layer 106. The conductive contact 124 is configured to electrically connect the active region (e.g., the doped region within the substrate 102) to a capacitor structure (e.g., the capacitor structure 126).

The conductive contact 124 may comprise material such as tungsten (W), cobalt (Co), zirconium (Zr), tantalum (Ta), titanium (Ti), aluminum (Al), ruthenium (Ru), copper (Cu), metal carbides (e.g., tantalum carbide (TaC), titanium carbide (TiC), or tantalum magnesium carbide (TaMaC)), metal nitrides (e.g., titanium nitride (TiN)), transition metal aluminides, or a combination thereof.

It should be noted that the conductive contact 124 is separated from the bit line structure 118 by a distance along the Y direction.

In some embodiments, the semiconductor device 100a may include the capacitor structure 126. The capacitor structure 126 may be disposed on the isolation layer 120 and over the bit line structure 118. The capacitor structure 126 may be electrically connected to the active region (e.g., the doped region within the substrate 102) via the conductive contact 124. The capacitor structure 126 may consist of a capacitor electrode 126a, a capacitor dielectric 126b, and a capacitor electrode 126c.

The capacitor electrode 126a may be disposed on the conductive contact 124 and electrically connected to the conductive contact 124. The capacitor electrode 126a may function as a lower electrode of the capacitor structure 126. In some embodiments, the capacitor electrode 126a may feature multiple vertical portions connected by horizontal segments to increase a capacitance of the capacitor structure 126. In some embodiments, the capacitor electrode 126a may be composed of materials such as tungsten (W), copper (Cu), ruthenium (Ru), iridium (Ir), nickel (Ni), osmium (Os), rhodium (Rh), aluminum (Al), molybdenum (Mo), cobalt (Co), alloys thereof, or a combination thereof.

The capacitor dielectric 126b may be disposed between the capacitor electrode 126a and the capacitor electrode 126c. The capacitor dielectric 126b may be conformally disposed on the capacitor electrode 126a. The capacitor dielectric 126b may include materials such as silicon oxide (SiO₂), silicon nitride (Si₃N₄), silicon oxynitride (N₂OSi₂), silicon nitride oxide (N₂OSi₂), or other suitable materials.

The capacitor electrode 126c may be disposed on the capacitor dielectric 126b and functions as an upper electrode of the capacitor structure 126. In some embodiments, the capacitor electrode 126c may be composed of materials such as tungsten (W), copper (Cu), ruthenium (Ru), iridium (Ir), nickel (Ni), osmium (Os), rhodium (Rh), aluminum (Al), molybdenum (Mo), cobalt (Co), alloys thereof, or a combination thereof.

Although not shown, the semiconductor device 100a may include additional components. For example, the semiconductor device 100a may feature a spacer surrounding the conductive contact 122 and/or the conductive contact 124. The spacer may consist of multiple dielectric layers, such as silicon oxide, silicon nitride, silicon oxynitride, silicon nitride oxide, high-k materials or a combination thereof. The spacer may also include an air gap between the dielectric layers, which may be covered by a landing pad. The landing pad may be electrically connected to the capacitor structure 126 and may consist of metals such as tungsten (W), copper (Cu), ruthenium (Ru), iridium (Ir), nickel (Ni), osmium (Os), rhodium (Rh), aluminum (Al), molybdenum (Mo), cobalt (Co), alloys thereof, or a combination thereof.

FIG. 1B is a partial enlarged view of a region R of the semiconductor device 100a shown in FIG. 1A in accordance with some embodiments of the present disclosure.

With reference to FIG. 1B, in some embodiments, the dielectric layer 112 may consist of a lower portion 112p1 and an upper portion 112p2 situated above the lower portion 112p1. The portions 112p1 and 112p2 may have different dimensions, such as a thickness or a length along the X direction. For example, the portion 112p1 may have a thickness T1, while the portion 112p2 may have a thickness T2 that is less than the thickness T1. In some embodiments, a ratio of the thickness T2 to the thickness T1 may range from about 0.2 to about 0.8, including values such as 0.2, 0.3, 0.4, 0.5, 0.6, 0.7, or 0.8. When the ratio falls within the specified range, the opening defined by the dielectric layer 112 may achieve a suitable aspect ratio, facilitating formation of the gate electrode 114, which is described below.

In some embodiments, the portions 112p1 and 112p2 of the dielectric layer 112 may define a step structure 112t, which may be located above the gate electrode 114. The step structure 112t may define an opening with varying aspect ratios. In some embodiments, the step structure 112t may overlap the dielectric layer 116.

In some embodiments, the gate electrode 114 may be positioned on a sidewall of the portion 112p1 of the dielectric layer 112. The gate electrode 114 may be in contact with the portion 112p1 of the dielectric layer 112. In some embodiments, a surface 112s1 (or an upper surface 112s1) of the portion 112p1 of the dielectric layer 112 may be elevated above a surface 102s1 (or an upper surface) of the substrate 102. The portion 112p1 of the dielectric layer 112 may contact or overlap the sidewall of the substrate 102 along the X direction. In some embodiments, the portion 112p1 of the dielectric layer 112 may contact or overlap the sidewall of the dielectric layer 106 along the X direction. In some embodiments, the portion 112p1 of the dielectric layer 112 may contact or overlap a portion of the sidewall of the dielectric layer 108 along the X direction.

The portion 112p2 is connected to and positioned directly above the portion 112p1. A surface 112s2 (or an upper surface) of the portion 112p2 may be elevated above the surface 112s1 of the dielectric layer 112. In some embodiments, the surface 112s2 of the dielectric layer 112 may also be at an elevation higher than an elevation of the surface 102s1 of the substrate 102. In some embodiments, the surface 112s1 may be exposed by the portion 112p2. In some embodiments, the surface 112s2 of the dielectric layer 112 may be at an elevation substantially equal to that of the upper surface (not annotated) of the dielectric layer 108 (or isolation structure). Furthermore, a length of the portion 112p2 along the Z direction may be less than a length of the portion 112p1. The portion 112p2 of the dielectric layer 112 may also contact or overlap a portion of the sidewall of the dielectric layer 108 along the X direction. In some embodiments, the portion 112p2 of the dielectric layer 112 may be spaced apart from the gate electrode 114.

In some embodiments, the dielectric structure 116 within the trench 110 may have a T-shaped profile. In some embodiments, the dielectric structure 116 may exhibit a step profile corresponding to the step 112t of the dielectric layer 112. The dielectric structure 116 may comprise a portion 116p1 located over the gate electrode 114 and a portion 116p2 situated above the portion 116p1. The portion 116p1 of the dielectric structure 116 may be in contact with the portion 112p1 of the dielectric layer 112, while the portion 116p2 of the dielectric structure 116 may be in contact with the portion 112p2 of the dielectric layer 112.

In some embodiments, the portion 116p1 may overlap the substrate 102, the dielectric layer 106 and a portion of the dielectric layer 108 along the X direction. Similarly, the portion 116p2 may overlap a portion of the dielectric layer 108 along the X direction. The portion 116p1 of the dielectric structure 116 may have a width (or an aperture) W1 along the X direction, and the portion 116p2 of the dielectric structure 116 may have a width (or an aperture) W2 along the same direction. In some embodiments, the width W2 may be greater than the width W1, with a ratio of the width W2 to the width W1 ranging from about 1.1 to about 1.5 (e.g., 1.1, 1.2, 1.3, 1.4, or 1.5). Furthermore, a ratio of the width (or the aperture) defined by the portion 112p2 to a width (or an aperture) defined by the portion 112p1 may also range from about 1.1 to about 1.5, facilitating the deposition of materials for the gate electrode 114.

FIG. 2 is a cross-sectional view of a semiconductor device 100b in accordance with some embodiments of the present disclosure. The semiconductor device 100b is similar to the semiconductor device 100a, and repeated descriptions are omitted.

With reference to FIG. 2, in some embodiments, a surface 114s1 (or an upper surface) of the gate electrode 114 may be positioned at an elevation that is substantially same as that of the surface 102s1 of the substrate 102. In some embodiments, the portion 116p1 of the dielectric structure 116 does not overlap the substrate 102 along the X direction. In some embodiments, a lower surface of the dielectric structure 116 may be located at an elevation that is substantially same as the elevation of the surface 102s1 of the substrate 102.

FIG. 3 is a cross-sectional view of a semiconductor device 100c in accordance with some embodiments of the present disclosure. The semiconductor device 100c is similar to the semiconductor device 100a and repeated descriptions are omitted.

With reference to FIG. 3, in some embodiments, the surface 114s1 of the gate electrode 114 may be substantially aligned with or coplanar with the surface 112s1 of the dielectric layer 112. In some embodiments, the surface 102s1 of the substrate 102 may be positioned at an elevation higher than a position of the surface 112s1 of the dielectric layer 112. In some embodiments, the portion 112p2 of the dielectric layer 112 may overlap the dielectric layer 106 along the X direction, and may also overlap the substrate 102 along the same direction.

FIG. 4 is a cross-sectional view of a semiconductor device 100d in accordance with some embodiments of the present disclosure. The semiconductor device 100d is similar to the semiconductor device 100a, and repeated descriptions are omitted.

With reference to FIG. 4, in some embodiments, the surface 112s1 of the dielectric layer 112 may be positioned at an elevation that is substantially same as the elevation of the surface 102s1 of the substrate 102. In some embodiments, the dielectric structure 116 within the trench 110 may have a substantially uniform width (or aperture) along the X direction. In some embodiments, the dielectric structure 116 does not overlap the portion 112p1 of the dielectric layer 112.

FIG. 5 is a cross-sectional view of a semiconductor device 100e in accordance with some embodiments of the present disclosure. The semiconductor device 100e is similar to the semiconductor device 100a, and repeated descriptions are omitted.

With reference to FIG. 5, an active area AA may be defined between two electrical isolation regions 104. The active area AA may include an upper region 102U and a lower region 102L. The upper region 102U may include a first doped region 109 located between two gate electrodes 114, and a second doped region 107 disposed between the gate electrode 114 and the electrical isolation region 104.

With reference to FIG. 5, the semiconductor device 100e may comprise a conductive plug 140, a capacitor electrode landing pad 150, and a capacitor structure 126′. In addition, the semiconductor device 100e may also comprise a conductive contact structure 123.

The conductive plug 140 may penetrate the dielectric structure 116, the dielectric layer 108, and the dielectric layer 106. The conductive plug 140 is configured to electrically connect an active region (e.g., the doped region 107) to a capacitor structure (e.g., the capacitor structure 126′). The conductive plug 140 includes a first part 140-1 disposed on the substrate 102 and a second part 140-2 disposed on the first part 140-1, wherein the second part 140-2 is exposed by the isolation structure (e.g., the dielectric layers 106 and/or 108) and is located in the dielectric structure 116. The conductive plug 140 may comprise material such as tungsten (W), cobalt (Co), zirconium (Zr), tantalum (Ta), titanium (Ti), aluminum (Al), ruthenium (Ru), copper (Cu), metal carbides (e.g., tantalum carbide (TaC), titanium carbide (TiC), or tantalum magnesium carbide (TaMaC)), metal nitrides (e.g., titanium nitride (TiN)), transition metal aluminides, or a combination thereof. Additionally, it should be noted that the capacitor structure 126′ is separated from the bit line structure 118 by a distance along the Y direction.

The capacitor electrode landing pad 150 covers the conductive plug 140 within the dielectric structure 116. In some embodiments, the conductive plug 140 is composed of copper, while the capacitor electrode landing pad 150 is made of Cu₃Ge. In some embodiments, the conductive plug 140 and capacitor electrode landing pad 150 may also be made of other materials. For instance, the conductive plug 140 may comprise tungsten or aluminum, and the capacitor electrode landing pad 150 may consist of gold, silver or aluminum.

The capacitor structure 126′ is similar to the capacitor structure 126 of the semiconductor device 100a shown in FIG. 1A, except that the capacitor structure 126′ includes a capacitor electrode 126a′, which comprises a lower portion 126a′-2 situated over the capacitor electrode landing pad 150 and an upper portion 126a′-1 positioned over the lower portion 126a′-2. The lower portion 126a′-2 is located between the upper portion 126a′-1 and the capacitor electrode landing pad 150. The lower portion 126a′-2 may have a tapered profile. The upper portion 126a′-1 is same as the capacitor electrode 126a of the semiconductor device 100a in FIG. 1A. Materials used for the upper portion 126a′-1 and the lower portion 126a′-2 may be same as those of the capacitor electrode 126a. In some embodiments, the capacitor electrode 126a′ may be electrically connected to the substrate 110 in the doped region 107 via the conductive plug 140.

The conductive contact structure 123 may be formed in the top surface 102s1 of the substrate 102 and may extend to the bit line structure 118. The conductive contact structure 123 may penetrate the dielectric structure 116, the dielectric layer 108, and the dielectric layer 106. The conductive contact structure 123 is configured to electrically connect the doped region 109 to the bit line structure 118. The conductive contact structure 123 may comprise a conductive contact 127, a conductive bottom electrode 129, a conductive top electrode 131, a conductive mask pattern 133, and a spacer 135.

The conductive contact 127 may be positioned in the doped region 109. A top surface 127-1 of the conductive contact 127 may be substantially coplanar with the top surface 102s1 of the substrate 102. Sidewalls 127-3 of the conductive contact 127 may be separated from the substrate 102. The conductive contact 127 may be formed of a conductive material such as doped polysilicon, metal, metal nitride, or metal silicide.

The conductive bottom electrode 129 may be positioned over the conductive contact 127. A bottom surface 129-2 of the conductive bottom electrode 129 may be substantially coplanar with the top surface 127-1 of the conductive contact 127. In some embodiments, the conductive bottom electrode 129 may be formed of doped polysilicon.

The conductive top electrode 131 may be positioned over the conductive bottom electrode 129. A bottom surface 131-2 of the conductive top electrode 131 may be substantially coplanar with a top surface 129-1 of the conductive bottom electrode 129. In some embodiments, the conductive top electrode 131 may be formed of tungsten, aluminum, copper, nickel, or cobalt.

The conductive mask pattern 133 may be positioned over the conductive top electrode 131. A bottom surface 133-2 of the conductive mask pattern 133 may be substantially coplanar with a top surface 131-1 of the conductive top electrode 131. In some embodiments, the conductive top electrode 131 may be formed of silicon oxide, silicon nitride, silicon oxynitride, or silicon nitride oxide.

The spacer 135 may be disposed on sidewalls 127-3, 129-3, 131-3, and 133-3 of the conductive contact 127, the conductive bottom electrode 129, the conductive top electrode 131, and the conductive mask pattern 133, respectively. A top surface 135-1 of the spacer 135 may be substantially coplanar with a top surface 133-1 of the conductive mask pattern 133. A bottom surface 135-2 of the spacer 135 may be substantially coplanar with a bottom surface 127-2 of the conductive contact 127. Sidewalls 127-3, 129-3, 131-3, 133-3 and 135-4 of the conductive contact 127, the conductive bottom electrode 129, the conductive top electrode 131, the conductive mask pattern 133, and the spacer 135 are substantially coplanar. In some embodiments, the spacer 135 may be formed of silicon oxide, silicon nitride, silicon oxynitride, or silicon nitride oxide.

FIGS. 6A to 6J illustrate stages of an exemplary method for manufacturing a semiconductor device in accordance with some embodiments of the present disclosure.

Referring to FIG. 6A, a substrate 102 may be provided, within which a plurality of electrical isolation regions 104 may be formed. A dielectric layer 106 may be formed over the substrate 102, followed by formation of a dielectric layer 108 on top of the dielectric layer 106.

In some embodiments, an etching process may be performed to remove a portion of the substrate 102, creating a recess, into which a dielectric material may be deposited to form the electrical isolation region 104. For example, the dielectric material may be deposited using methods such as chemical vapor deposition (CVD), atomic layer deposition (ALD), physical vapor deposition (PVD), low-pressure chemical vapor deposition (LPCVD), flowable chemical vapor deposition (FCVD), or another suitable process. Similarly, the dielectric layers 106 and 108 may be formed using CVD, ALD, PVD, LPCVD, FCVD, or another suitable process.

Referring to FIG. 6B, a trench 110 may be formed. In some embodiments, an etching process may be employed to remove a portion of the substrate 102, the dielectric layer 106, and the dielectric layer 108. The etching process may include wet etching, dry etching, or other suitable processes.

Referring to FIG. 6C, a dielectric material layer 112a may be deposited to cover an upper surface of the dielectric layer 108 and lateral surfaces of the substrate 102, the dielectric layer 106, and the dielectric layer 108. A portion of the dielectric material layer 112a may be located within the trench 110. The dielectric material layer 112a may be formed using methods such as chemical vapor deposition (CVD), atomic layer deposition (ALD), physical vapor deposition (PVD), low-pressure chemical vapor deposition (LPCVD), flowable chemical vapor deposition (FCVD), or another suitable process.

Referring to FIG. 6D, a filling material 128 may be formed within the trench 110. The filling material 128 may include a photosensitive material, such as photoresist or other suitable materials, and may cover a portion of the dielectric material layer 112a. In some embodiments, the filling material 128 may be applied using coating or other suitable processes.

In some embodiments, the filling material 128 may be formed over the dielectric layer 108 to fill the trench 110, with a portion of the filling material 128 subsequently removed using an etching process. The removal process ensures that an upper surface of the filling material 128 is lower than the upper surface of the dielectric layer 108. In some embodiments, the upper surface of the filling material 128 may be higher than a surface 102s1 of the substrate 102 or higher than an upper surface of the dielectric layer 106.

Referring to FIG. 6E, an etching process P1 may be performed to remove a portion of the dielectric material layer 112a, thereby defining a dielectric layer 112 with portions 112p1 and 112p2. The etching process may partially remove the dielectric material layer 112a over the filling material 128, resulting in the portions 112p1 and 112p2 having different thicknesses or lengths along the X direction. The etching process P1 may include wet etching, dry etching, or other suitable processes.

Referring to FIG. 6F, the filling material 128 may be removed, resulting in the dielectric layer 112 defining an opening 130. The opening 130 consists of two parts: a part 130t1 and a part 130t2, with the part 130t2 positioned over the part 130t1. The part 130t2 of the opening 130 has a greater aperture defined by the portion 112p2 of the dielectric layer 112, while the part 130t1 has a smaller aperture defined by the portion 112p1 of the dielectric layer 112. In some embodiments, a ratio of the aperture of the part 130t2 to the aperture of the part 130t1 may range from about 1.1 to about 1.5, including 1.1, 1.2, 1.3, 1.4, or 1.5.

Referring to FIG. 6G, a conductive material 114′ may be formed. At this stage, the greater aperture of the part 130t2 of the opening 130 facilitates deposition of the conductive material 114′, allowing the conductive material 114′ to reach a bottom of the opening 130 with few or no voids. The conductive material 114′ may be deposited using a process such as physical vapor deposition (PVD), chemical vapor deposition (CVD), atomic layer deposition (ALD), low-pressure chemical vapor deposition (LPCVD), flowable chemical vapor deposition (FCVD), or another suitable process.

Referring to FIG. 6H, a portion of the conductive material 114′ may be removed to produce a gate electrode 114. The portions 112p1 and 112p2 of the dielectric layer 112 may be exposed by the gate electrode 114. In some embodiments, a surface 114s1 of the gate electrode 114 may be lower than the surface 102s1 of the substrate 102. In other embodiments, the surface 114s1 of the gate electrode 114 may be substantially aligned with the surface 102s1 of the substrate 102 along the X direction. Additionally, in some embodiments, extra conductive materials may be formed over the gate electrode 114, with upper surfaces of the extra conductive materials substantially aligned with the surface 102s1 of the substrate 102 along the X direction. The conductive material 114′ may be removed using an etching process, such as dry etching, wet etching, or other suitable processes.

Referring to FIG. 6I, a dielectric structure 116 may be formed to fill the trench 110 or the opening 130. The dielectric structure 116 may also cover the dielectric layer 108. The dielectric structure 116 may be formed using chemical vapor deposition (CVD), atomic layer deposition (ALD), physical vapor deposition (PVD), low-pressure chemical vapor deposition (LPCVD), flowable chemical vapor deposition (FCVD), or another suitable process.

Referring to FIG. 6J, a bit line structure 118 may be formed over the dielectric structure 116. An isolation layer 120 may then be formed over the bit line structure 118. A conductive contact 122 may be established between the substrate 102 and the bit line structure 118, while another conductive contact 124 may penetrate both the dielectric structure 116 and the isolation layer 120. In some embodiments, a capacitor structure 126, which includes a capacitor electrode 126a, a capacitor dielectric 126b, and a capacitor electrode 126c, may be formed over the isolation layer 120 and electrically connected to the conductive contact 124. As a result, a semiconductor device (e.g., the semiconductor device 100a as shown in FIG. 1A) may be produced.

Additionally, instead of the conductive contacts 122 and 124 and the capacitor structure 126, some embodiments may include a conductive plug 140, a capacitor electrode landing pad 150, a conductive contact structure 123, and a capacitor structure 126′, thereby creating a semiconductor device 100e as shown in FIG. 5. Features of the conductive plug 140, the capacitor electrode landing pad 150, the conductive contact structure 123, and the capacitor structure 126′ are described with reference to FIG. 5, and repeated descriptions are omitted.

FIG. 7 is a flowchart illustrating a method 200 of manufacturing a semiconductor device in accordance with some embodiments of the present disclosure.

The method 200 begins with operation 202, wherein a substrate 102 is provided. An isolation structure, including dielectric layers 106 and/or 108, is formed over the substrate 102. FIG. 6A illustrates the stage corresponding to operation 202.

The method 200 continues with operation 204, wherein portions of the isolation structure (e.g., the dielectric layers 106 and/or 108) and the substrate 102 are removed, thereby forming a trench 110. FIG. 6B illustrates the stage corresponding to operation 204.

The method 200 continues with operation 206, wherein a dielectric layer 112a is formed within the trench 110. FIG. 6C illustrates the stage corresponding to operation 206.

The method 200 continues with operation 208, wherein a filling material 128 is formed within the trench 110. FIG. 6D illustrates the stage corresponding to operation 208.

The method 200 continues with operation 210, wherein an etching process P1 is performed to remove an upper portion of the dielectric layer 112a that is exposed by the filling material 128. The etching process results in formation of a dielectric layer 112 within the trench 110a, consisting of a lower portion 112p1 and an upper portion 112p2, wherein a thickness of the lower portion 112p1 is greater than a thickness of the upper portion 112p2. FIG. 6E illustrates the stage corresponding to operation 210.

The method 200 continues with operation 212, wherein the filling material 128 is removed, resulting in the formation of an opening 130 defined by the dielectric layer 120. The opening 130 comprises an upper portion 130t2 and a lower portion 130t1, with the upper portion 130t2 having an aperture greater than an aperture of the lower portion 130t1. FIG. 6F illustrates the stage corresponding to operation 212.

The method 200 continues with operation 214, wherein a conductive material 114′ is deposited into the opening 130 defined by the dielectric layer 120. FIG. 6G illustrates the stage corresponding to operation 214.

The method 200 continues with operation 216, wherein a portion of the conductive material 114′ is removed to form a gate electrode (or a word line) 114 within the opening 130 defined by the dielectric layer 120. FIG. 6H illustrates the stage corresponding to operation 216.

The method 200 continues with operation 218, wherein a dielectric layer 120, a bit line 118, and a capacitor structure 126 are formed. In addition, conductive contacts 122 and 124 also are formed. As a result, a semiconductor device 100a is produced. FIGS. 6I and 6J illustrate the stages corresponding to operation 218.

The method 200 is merely an example, and is not intended to limit the present disclosure beyond what is explicitly recited in the claims. Additional operations may be provided before, during, or after each operation of the method 200, and some operations described may be replaced, eliminated, or reordered for additional embodiments of the method. In some embodiments, the method 200 may include further operations not depicted in FIG. 7. In some embodiments, the method 200 may include one or more operations depicted in FIG. 7.

One aspect of the present disclosure provides a semiconductor device. The semiconductor device comprises a substrate with a top surface, wherein the substrate includes an active area comprising an upper region and a lower region, wherein the upper region contains a plurality of doped regions; a dielectric layer at least partially embedded within the substrate; a gate electrode spaced apart from the substrate by a first portion of the dielectric layer; and a bit line positioned in and protruding from the active area. The dielectric layer includes the first portion with a first thickness and a second portion with a second thickness less than the first thickness. The bit line comprises a bit line contact located in the upper region of the active area. A top surface of the bit line contact is at a vertical level same as a vertical level of the top surface of the substrate.

In some embodiments, the bit line is positioned between two of the gate electrodes.

In some embodiments, the bit line is configured to electrically connect one of the doped regions to a bit line structure.

In some embodiments, the bit line comprises a bit line bottom electrode, a bit line top electrode, a bit line mask pattern, and a bit line spacer.

In some embodiments, a bottom surface of the bit line bottom electrode is substantially coplanar with the top surface of the bit line contact; a bottom surface of the bit line top electrode is substantially coplanar with a top surface of the bit line bottom electrode; and a bottom surface of the bit line mask pattern is substantially coplanar with a top surface of the bit line top electrode.

In some embodiments, a top surface of the bit line spacer is substantially coplanar with a top surface of the bit line mask pattern, and a bottom surface of the bit line spacer is substantially coplanar with a bottom surface of the bit line contact.

In some embodiments, sidewalls of the bit line contact, the bit line bottom electrode, the bit line top electrode, the bit line mask pattern, and the bit line spacer are substantially coplanar.

In some embodiments, the semiconductor device further comprises a conductive plug positioned on the substrate, configured to electrically connect to one of the doped regions of the active area; a capacitor electrode landing pad disposed over and covering the conductive plug; and a capacitor structure disposed over the capacitor electrode landing pad and electrically connected to the conductive plug.

In some embodiments, the capacitor structure comprises a capacitor bottom electrode disposed over the capacitor electrode landing pad, a capacitor top electrode disposed over the capacitor bottom electrode, and a capacitor dielectric disposed between the capacitor bottom electrode and the capacitor top electrode, wherein the capacitor bottom electrode includes a lower portion disposed over the capacitor electrode landing pad and an upper portion disposed over the lower portion.

In some embodiments, the lower portion of the capacitor bottom electrode has a tapered profile.

Another aspect of the present disclosure provides a semiconductor device. The semiconductor device comprises a substrate; a gate dielectric embedded within the substrate; a gate electrode spaced apart from the substrate by the gate dielectric; a dielectric structure disposed over the gate electrode; a bit line positioned in a top surface of the substrate and between two of the gate electrodes; a conductive plug positioned on the substrate and electrically connected to a doped region of the substrate; and a capacitor disposed over and electrically connected to the conductive plug. The dielectric structure includes a step profile. The conductive plug consists of a first part disposed on the substrate and a second part disposed on the first part and within the dielectric structure.

In some embodiments, the semiconductor device further comprises a capacitor electrode landing pad disposed over and covering the conductive plug.

In some embodiments, the bit line is configured to electrically connect one of the doped regions to a bit line structure.

In some embodiments, the bit line comprises a bit line bottom electrode, a bit line top electrode, a bit line mask pattern, and a bit line spacer.

In some embodiments, a bottom surface of the bit line bottom electrode is substantially coplanar with a top surface of a bit line contact; a bottom surface of the bit line top electrode is substantially coplanar with a top surface of the bit line bottom electrode; and a bottom surface of the bit line mask pattern is substantially coplanar with a top surface of the bit line top electrode.

In some embodiments, a top surface of the bit line spacer is substantially coplanar with a top surface of the bit line mask pattern, and a bottom surface of the bit line spacer is substantially coplanar with a bottom surface of the bit line contact.

In some embodiments, sidewalls of the bit line contact, the bit line bottom electrode, the bit line top electrode, the bit line mask pattern, and the bit line spacer are substantially coplanar.

In some embodiments, the capacitor structure comprises a capacitor bottom electrode disposed on the capacitor electrode landing pad, a capacitor top electrode disposed over the capacitor bottom electrode, and a capacitor dielectric disposed between the capacitor bottom electrode and the capacitor top electrode. The capacitor bottom electrode includes a lower portion disposed over the capacitor electrode landing pad and an upper portion disposed over the lower portion.

In some embodiments, the lower portion of the capacitor bottom electrode has a tapered profile.

In some embodiments, the second part of the conductive plug is formed using an electroplating process.

Another aspect of the present disclosure provides a method of manufacturing a semiconductor device. The method comprises providing a substrate with a top surface; forming an active area in the substrate, wherein the active area includes an upper region and a lower region, wherein the upper region includes a plurality of doped regions; forming a dielectric layer at least partially embedded within the substrate; forming a gate electrode spaced apart from the substrate by the dielectric layer; and forming a bit line in and protruding from the active area of the substrate, wherein the bit line comprises a bit line contact in the upper region of the active area, and a top surface of the bit line contact is at a vertical level same as a vertical level of the top surface of the substrate.

In some embodiments, the formation of the dielectric layer comprises forming a first portion of the dielectric layer with a first thickness and forming a second portion with a second thickness less than the first thickness.

In some embodiments, the formation of the bit line further comprises forming a bit line bottom electrode over the bit line contact; forming a bit line top electrode over the bit line bottom electrode; forming a bit line mask pattern over the bit line top electrode; and forming a bit line spacer on sidewalls of the bit line contact, the bit line bottom electrode, the bit line top electrode, and the bit line mask pattern.

In some embodiments, a bottom surface of the bit line bottom electrode is substantially coplanar with the top surface of the bit line contact; a bottom surface of the bit line top electrode is substantially coplanar with a top surface of the bit line bottom electrode; and a bottom surface of the bit line mask pattern is substantially coplanar with a top surface of the bit line top electrode.

In some embodiments, a top surface of the bit line spacer is substantially coplanar with a top surface of the bit line mask pattern, and a bottom surface of the bit line spacer is substantially coplanar with a bottom surface of the bit line contact.

In some embodiments, the method further comprises forming a conductive plug on the substrate; forming a capacitor electrode landing pad over and covering the conductive plug; and forming a capacitor structure over the capacitor electrode landing pad and electrically connected to the conductive plug.

Another aspect of the present disclosure provides a method of manufacturing a semiconductor device. The method comprises providing a substrate; forming a gate dielectric at least partially embedded within the substrate; forming a gate electrode spaced apart from the substrate by the gate dielectric; forming an isolation structure over the substrate and surrounding the gate dielectric; forming a dielectric structure over the gate electrode and the isolation structure; forming a bit line in a top surface of the substrate and between two of the gate electrodes; forming a conductive plug over the substrate; forming a capacitor electrode landing pad over and covering the conductive plug; and forming a capacitor over and electrically connected to the conductive plug. The dielectric structure includes a step profile. The conductive plug includes a first part disposed within the isolation structure and a second part disposed over the first part and exposed by the isolation structure. The formation of the capacitor electrode landing pad comprises electroplating the second part of the conductive plug.

In some embodiments, the formation of the bit line further comprises forming a bit line bottom electrode over the bit line contact; forming a bit line top electrode over the bit line bottom electrode; forming a bit line mask pattern over the bit line top electrode; and forming a bit line spacer on sidewalls of the bit line contact, the bit line bottom electrode, the bit line top electrode, and the bit line mask pattern.

In some embodiments, the formation of the capacitor structure comprises forming a capacitor bottom electrode over the capacitor electrode landing pad; forming a capacitor top electrode over the capacitor bottom electrode; and forming a capacitor dielectric between the capacitor bottom electrode and the capacitor top electrode.

In some embodiments, the formation of the capacitor bottom electrode comprises forming a lower portion over the capacitor electrode landing pad and forming an upper portion over the lower portion.

The embodiments of the present disclosure illustrate a semiconductor device that includes a dielectric layer located within a trench defined by a substrate. The dielectric layer features a lower portion with a greater thickness and an upper portion with a smaller thickness. This structure facilitates deposition of a conductive material(s) to form a gate electrode without formation of voids within the trench, thereby enhancing a performance of the semiconductor device.

Although the present disclosure and its advantages have been described in detail, it should be understood that various changes, substitutions and alterations may be made herein without departing from the spirit and scope of the disclosure as defined by the appended claims. For example, many of the processes discussed above may be implemented in different methodologies and replaced by other processes, or a combination thereof.

Moreover, the scope of the present application is not intended to be limited to the particular embodiments of the process, machine, manufacture, composition of matter, means, methods and steps described in the specification. As one of ordinary skill in the art will readily appreciate from the present disclosure, processes, machines, manufacture, compositions of matter, means, methods, or steps, presently existing or later to be developed, that perform substantially the same function or achieve substantially the same result as the corresponding embodiments described herein, may be utilized according to the present disclosure. Accordingly, the appended claims are intended to include within their scope such processes, machines, manufacture, compositions of matter, means, methods, and steps.

What is claimed is:

1. A semiconductor device, comprising:
a substrate with a top surface, wherein the substrate includes an active area comprising an upper region and a lower region, wherein the upper region contains a plurality of doped regions;
a dielectric layer at least partially embedded within the substrate, wherein the dielectric layer includes a first portion with a first thickness and a second portion with a second thickness less than the first thickness;
a gate electrode spaced apart from the substrate by the first portion of the dielectric layer; and
a bit line positioned in and protruding from the active area, wherein the bit line comprises a bit line contact located in the upper region of the active area, and wherein a top surface of the bit line contact is at a vertical level same as a vertical level of the top surface of the substrate.

2. The semiconductor device of claim 1, wherein the bit line is positioned between two of the gate electrodes.

3. The semiconductor device of claim 2, wherein the bit line is configured to electrically connect one of the doped regions to a bit line structure.

4. The semiconductor device of claim 3, wherein the bit line comprises a bit line bottom electrode, a bit line top electrode, a bit line mask pattern, and a bit line spacer.

5. The semiconductor device of claim 4, wherein a bottom surface of the bit line bottom electrode is substantially coplanar with the top surface of the bit line contact; a bottom surface of the bit line top electrode is substantially coplanar with a top surface of the bit line bottom electrode; and a bottom surface of the bit line mask pattern is substantially coplanar with a top surface of the bit line top electrode.

6. The semiconductor device of claim 5, wherein a top surface of the bit line spacer is substantially coplanar with a top surface of the bit line mask pattern, and a bottom surface of the bit line spacer is substantially coplanar with a bottom surface of the bit line contact.

7. The semiconductor device of claim 6, wherein sidewalls of the bit line contact, the bit line bottom electrode, the bit line top electrode, the bit line mask pattern, and the bit line spacer are substantially coplanar.

8. The semiconductor device of claim 1, further comprising:
a conductive plug positioned on the substrate and configured to electrically connect to one of the doped regions of the active area;
a capacitor electrode landing pad disposed over and covering the conductive plug; and
a capacitor structure disposed over the capacitor electrode landing pad and electrically connected to the conductive plug.

9. The semiconductor device of claim 8, wherein the capacitor structure comprises:
a capacitor bottom electrode disposed over the capacitor electrode landing pad;
a capacitor top electrode disposed over the capacitor bottom electrode; and
a capacitor dielectric disposed between the capacitor bottom electrode and the capacitor top electrode,
wherein the capacitor bottom electrode includes a lower portion disposed over the capacitor electrode landing pad and an upper portion disposed over the lower portion.

10. The semiconductor device of claim 1, wherein the lower portion of the capacitor bottom electrode has a tapered profile.

11. A semiconductor device, comprising:
a substrate;
a gate dielectric embedded within the substrate;
a gate electrode spaced apart from the substrate by the gate dielectric;
a dielectric structure disposed over the gate electrode, wherein the dielectric structure includes a step profile;
a bit line positioned in a top surface of the substrate and between two of the gate electrodes;
a conductive plug positioned on the substrate and electrically connected to a doped region of the substrate, wherein the conductive plug includes a first part disposed on the substrate and a second part disposed on the first part and in the dielectric structure; and
a capacitor disposed over and electrically connected to the conductive plug.

12. The semiconductor device of claim 11, further comprising:
a capacitor electrode landing pad disposed over and covering the conductive plug.

13. The semiconductor device of claim 12, wherein the bit line is configured to electrically connect one of the doped regions to a bit line structure.

14. The semiconductor device of claim 13, wherein the bit line comprises a bit line bottom electrode, a bit line top electrode, a bit line mask pattern, and a bit line spacer.

15. The semiconductor device of claim 14, wherein a bottom surface of the bit line bottom electrode is substantially coplanar with a top surface of a bit line contact; a bottom surface of the bit line top electrode is substantially coplanar with a top surface of the bit line bottom electrode; and a bottom surface of the bit line mask pattern is substantially coplanar with a top surface of the bit line top electrode.

16. The semiconductor device of claim 15, wherein a top surface of the bit line spacer is substantially coplanar with a top surface of the bit line mask pattern, and a bottom surface of the bit line spacer is substantially coplanar with a bottom surface of the bit line contact.

17. The semiconductor device of claim 16, wherein sidewalls of the bit line contact, the bit line bottom electrode, the bit line top electrode, the bit line mask pattern, and the bit line spacer are substantially coplanar.

18. The semiconductor device of claim 17, wherein the capacitor comprises:
a capacitor bottom electrode disposed on the capacitor electrode landing pad;
a capacitor top electrode disposed over the capacitor bottom electrode; and
a capacitor dielectric disposed between the capacitor bottom electrode and the capacitor top electrode,
wherein the capacitor bottom electrode includes a lower portion disposed over the capacitor electrode landing pad and an upper portion disposed over the lower portion.

19. The semiconductor device of claim 18, wherein the lower portion of the capacitor bottom electrode has a tapered profile.

20. The semiconductor device of claim 19, wherein the second part of the conductive plug is formed using an electroplating process.
